(19) United States
(12) Patent Application Publication
(10) Pub. No.: US 2011/0299231 A1
(43) Pub. Date: Dec. 8, 2011

(54) Rotatable Cases For Electronic Devices

(76) Inventors: Scott Carter Gaddis, II, Louisville, KY (US); Steven Neel Ford, Owensboro, KY (US)

(21) Appl. No.: 13/088,749

(22) Filed: Apr. 18, 2011

Related U.S. Application Data
(60) Provisional application No. 61/352,024, filed on Jun. 7, 2010.

(51) Int. Cl. H05K 5/00; H05K 5/02

(52) U.S. Cl. 361/679.01; 312/244

(57) ABSTRACT

Embodiments of cases for electronic devices include a shell that includes a display opening and a handle coupled to the shell. The shell is adapted to at least partially surround the electronic device. The handle is adapted to rotate relative to the shell about an axis of rotation. The handle is also adapted to support the case in a free-standing condition in a portrait orientation and a landscape orientation.

### CROSS REFERENCE TO RELATED APPLICATIONS

This application claims priority under 35 U.S.C. §119 to U.S. Provisional Application Ser. No. 61/352,024, filed Jun. 7, 2010, and titled “360 Degree Rotatable Sleeve for Electronic Devices.”

### TECHNICAL FIELD

The present disclosure is generally directed to cases for electronic devices and, in particular, to cases for electronic devices including hand-holding features.

### BACKGROUND

Cases for electronic devices are used by users who wish to provide protection to electronic devices, particularly devices that are portable. Cases may allow users to interact with the electronic devices through the original interface of the electronic devices, while providing resilient surfaces that protect the electronic devices from abrasion, impact, and/or compression.

As the size and weight of electronic devices grow, it may become increasingly uncomfortable for a user to support the electronic devices through grasping the case alone with the user's fingers. Further, a user may prefer to interact and/or view the electronic device in a free-standing condition, without having to support the electronic device. Accordingly, cases that improve the ergonomics of supporting electronic devices in the hand of a user and allow the electronic device to be supported in a free-standing condition without further intervention of the user are required.

### SUMMARY

According to one embodiment, a case for an electronic device includes a shell that includes a display opening and a handle coupled to the shell. The shell is adapted to at least partially surround the electronic device. The handle is adapted to rotate relative to the shell about an axis of rotation.

According to another embodiment, a case for an electronic device includes a shell and a handle. The shell is adapted to at least partially surround the electronic device. The shell includes a first shell portion and a second shell portion, where the first shell portion includes a display opening passing through a bezel. The handle is coupled to the second shell portion and is adapted to rotate relative to the shell about an axis of rotation.

According to yet another embodiment, a case for an electronic device includes a shell and a handle. The shell includes a first shell portion, a hinge portion, and a second shell portion. The first shell portion includes a bezel and a display opening that passes through the bezel. The second shell portion includes a plurality of control feature openings. The first shell portion and the second shell portion at least partially surround the electronic device. The handle is coupled to the second shell portion, and is rotatable relative to the shell about an axis of rotation.

These and additional objects and advantages provided by the embodiments of the present invention will be more fully understood in view of the following detailed description, in conjunction with the drawings.

### BRIEF DESCRIPTION OF THE DRAWINGS

The following detailed description of specific embodiments of the present disclosure can be best understood when read in conjunction with the drawings enclosed herewith.

FIG. 1 is an exploded perspective rear view of a case for an electronic device;

FIG. 2 is a front view of a handle for a case for an electronic device;

FIG. 3 is a side view of a handle for a case for an electronic device;

FIG. 4 is a perspective front view of a case for an electronic device;

FIG. 5 is a sectional top view of a case for an electronic device, wherein the case is in an open orientation;

FIG. 6 is a sectional top view of a case for an electronic device, wherein the case is in a closed orientation with the electronic device enclosed therein;

FIG. 7 is a perspective front view of a case for an electronic device;

FIG. 8 is a perspective rear view of a case for an electronic device;

FIG. 9 is a perspective front view of a case for an electronic device; and

FIG. 10 is a perspective top view of a case for an electronic device.

The embodiments set forth in the drawings are illustrative in nature and not intended to be limiting of the subject matter defined by the claims. Moreover, individual features of the drawings and examples will be more fully apparent and understood in view of the detailed description.

### DETAILED DESCRIPTION

Embodiments of the present disclosure are directed to rotatable cases for electronic devices. Rotatable cases according to the present disclosure include a handle coupled to a shell that at least partially surrounds the electronic device. The handle allows a user to securely hold the case, and therefore the electronic device, while interacting with the electronic device. The handle is adapted to rotate about the shell such that a user can reposition the electronic device through 360 degrees of rotation. Further, the handle includes a support end that may extend away from the shell. The support end may be deployed by a user to support the case in a free-standing position in either a landscape orientation or a portrait orientation.

As used herein, “landscape orientation” and “portrait orientation” refer to the rotational orientation of an electronic device that has a rectangular display. Specifically, “landscape orientation” refers to viewing the electronic device such that the longer side of the rectangular display is approximately horizontal, while the shorter side of the rectangular display is approximately vertical. In contrast, “portrait orientation” refers to viewing the electronic device such that the longer side of the rectangular display is approximately vertical, while the shorter side of the rectangular display is approximately horizontal.

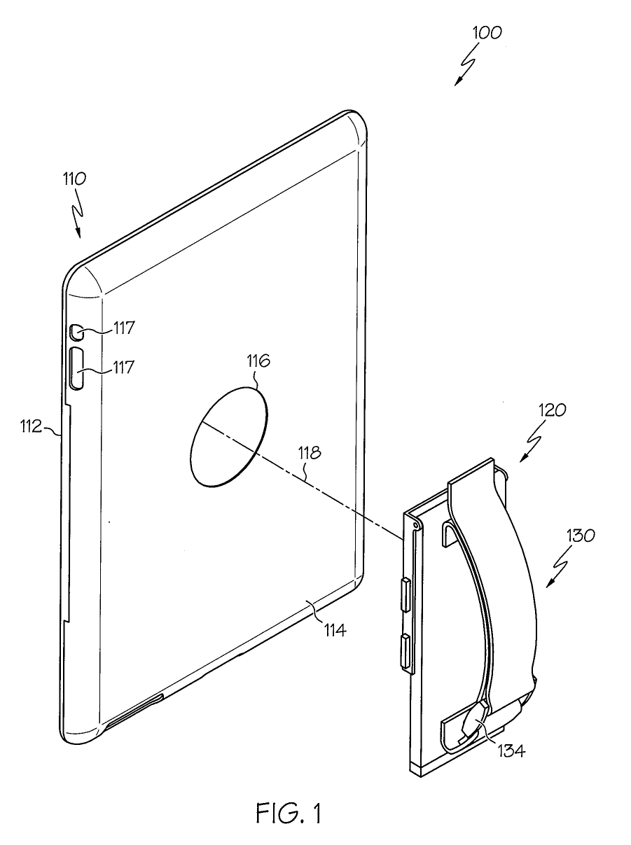

FIG. 1 depicts a case 100 for an electronic device 90 according to one embodiment. The case 100 includes a shell 110 and a handle 120. The shell 110 includes a first shell portion 112 and a second shell portion 114. A circular opening 116 is disposed along the second shell portion 114 of the shell 110. The circular opening 116 defines an axis of rotation 118 along the center of the circular opening 116. The handle 120 is secured to the circular opening 116 along the second shell portion 114 such that the handle 120 is free to rotate 360 degrees about the axis of rotation 118 relative to the shell 110. Embodiments of the handle 120 may include a grip handle, an elastic securing strap for either hand or for securing the electronic device 90 within the shell 110 to another surface, a gloved handle, or any other fastener that operates to removably attach the shell 110 to an anchoring surface. Although opening 116 is described and shown as circular in shape, it is understood that opening 116 may comprise any shape.

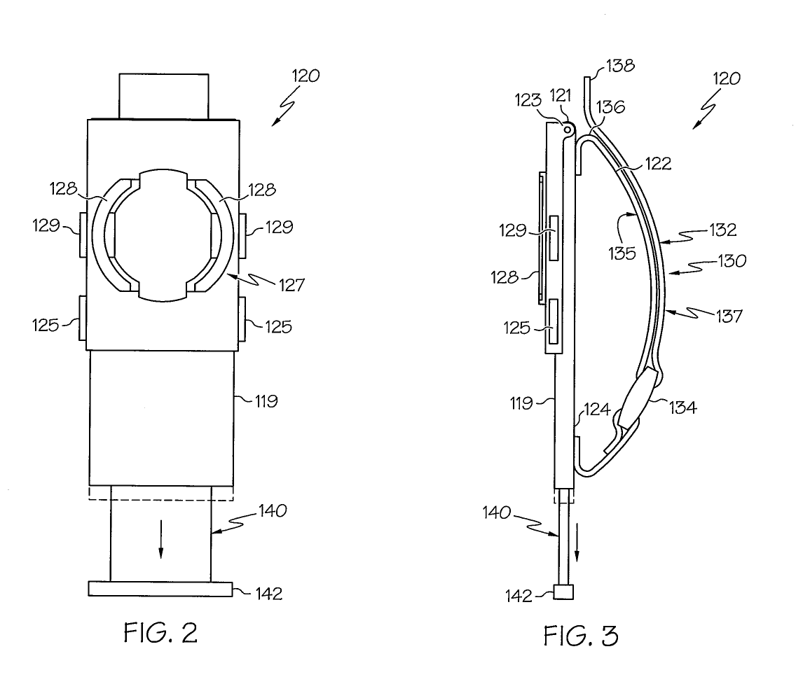

Referring to FIG. 2, the handle 120 includes a retention element 127 that secures the handle 120 to the circular opening 116 of the shell 110. The retention element 127 includes at least one retention key 128 that a user may actuate as to engage and/or disengage the retention element 127 with the circular opening 116. In the embodiment depicted in FIG. 2, the retention keys 128 are formed from semi-circular portions that extend from the handle bracket 119. The retention keys 128 may be elastically biased outwards by, for example, springs or compliant supports, such that the retention keys 128 press outwards to engage the circular opening 116. The retention keys 128 may include retention actuation pads 129 along the outside of the retention keys 128, which enable a user to depress the retention keys 128 as to disengage the retention element 127 from the circular opening 116 when the handle 120 is coupled to the shell 110.

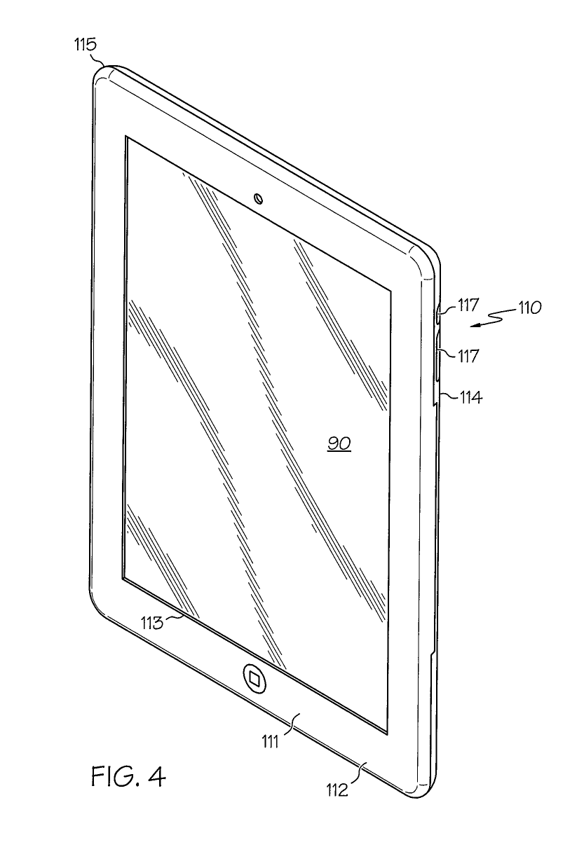

The handle 120 depicted in FIG. 2 also includes a set of stand actuation pads 125. The stand actuation pads 125 selectively engage the handle bracket 119 with the retention element 127. The stand actuation pads 125 may be actuated by a user to unlock the handle bracket 119 from the retention element 127, thereby allowing the handle bracket 119 to be pivoted about the handle hinge 123 as shown in FIG. 3. The handle 120 further includes a support end 140 that extends along one end of the handle bracket 119. The support end 140 includes a contact surface 142 that includes a high friction material. The high friction material may have a static coefficient of friction that is greater than 0.4. Examples of such materials that exhibit this property include silicone rubber and acrylic rubber. The support end 140 may also extend along the handle bracket 119, thereby increasing the length from the shell 110 to the contact surface 142 measured along from the handle 120.

With the handle bracket 119 pivoted away from the retention element 127, and therefore the shell 110, the support end 140 and a portion of the second shell portion 114 of the shell 110 may be placed into contact with a surface as to maintain the case 100 and the enclosed electronic device 90 in a free-standing position.

Still referring to FIG. 3, the handle 120 also includes an extendible strap assembly 130. The extendible strap assembly 130, together with the handle bracket 119, creates an internal envelope 122 into which a user can insert his or her hand. The extendible strap assembly 130 increases and decreases in length to provide adjustment to the size of the internal envelope 122 such that the internal envelope 122 can be adjusted to accommodate hands of differing sizes.

The extendible strap assembly 130 includes a tongue 132 attached to a first portion 121 of the handle bracket 119 and a cinch ring 134 coupled to a second portion 124 of the handle bracket 119. The tongue 132 includes a first tongue section 135, which includes one of a hook material or a loop material 136 and a second tongue section 137, which includes one of a loop material or a hook material 138 adapted to engage the hook material or loop material 136 of the first tongue section 135. The second tongue portion 137 passes through the cinch ring 134 and is doubled back onto the first tongue portion 135, where the adjacent hook material and loop material 136, 138 are affixed to one another. The size of the internal envelope 122 can therefore be adjusted by a user by detaching the second tongue portion 137 from the first tongue portion 135, repositioning the tongue 132 within the cinch ring 134, and reaffixing the second tongue portion 137 to the first tongue portion 135.

Referring now to FIG. 4, the shell 110 of the case 100 includes a display opening 113 that passes through the first shell portion 112. The display opening 113 may include a transparent film that provides protection to at least one of the surfaces of the electronic device 90. Alternately, the display opening 113 may include an opening that allows unconstrained access to the electronic device 90. The display opening 113 allows a user to view the screen of the electronic device 90, and for electronic devices 90 that incorporate touchscreens, the display opening 113 allows the user to control the electronic device 90 through contact with the touchscreen. The shell 110 may also include at least one control opening 117. The control openings 117 are aligned with the additional control features of the electronic device 90, for example, a volume rocker switch, a lock button, a camera, and a charging port. The control openings 117 provide access to such control features without having to remove the electronic device 90 from the shell 110.

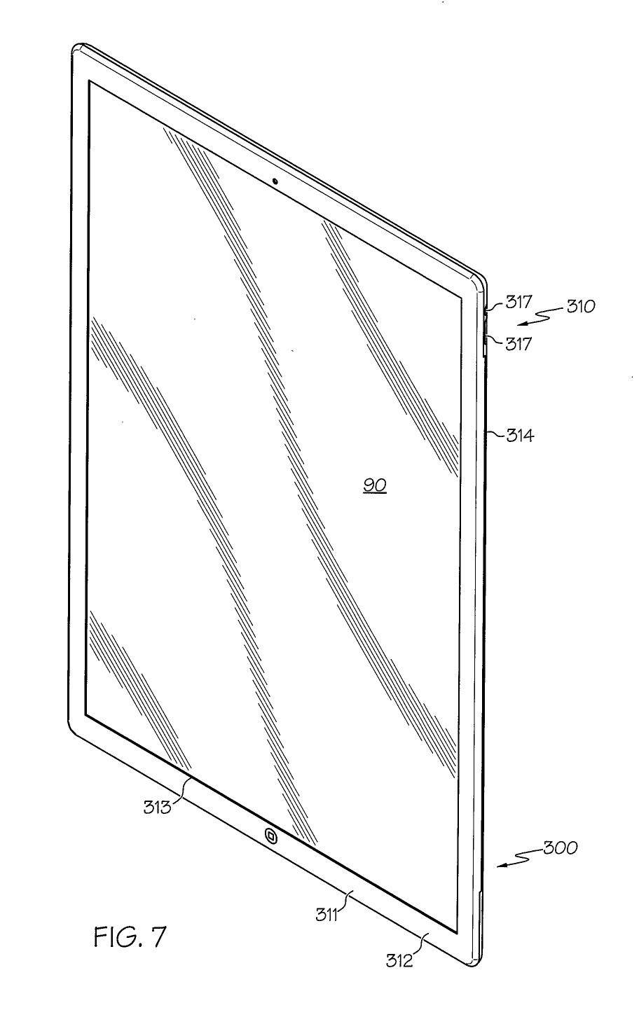

One embodiment of the case 100 may include a shell 110 that includes a “clam shell” design, where the electronic device 90 is secured within a shell 110 that articulates between an opened position and a closed position, as depicted in FIGS. 4-6. In this embodiment, the first shell portion 112 is connected to the second shell portion 114 through a hinge portion 115. In this embodiment, the hinge portion 115 is integrated into both the first shell portion 112 and the second shell portion 114; however, other embodiments may include a discrete hinge attached to both the first and second shell portions 112, 114.

In the embodiment, depicted in FIGS. 4-6, the first shell portion 112 includes a bezel 111 and a display opening 113. The bezel 111 is dimensionally smaller than the overall dimensions of the electronic device 90 such that the shell 110 at least partially surrounds a generally cuboid electronic device 90 along six faces. The display opening 113 passes through the first shell portion 112 and through the bezel 111. The display opening 113 is sized such that a user may continue to operate and interact with the electronic device 90 through the use of the user interface of the electronic device 90.

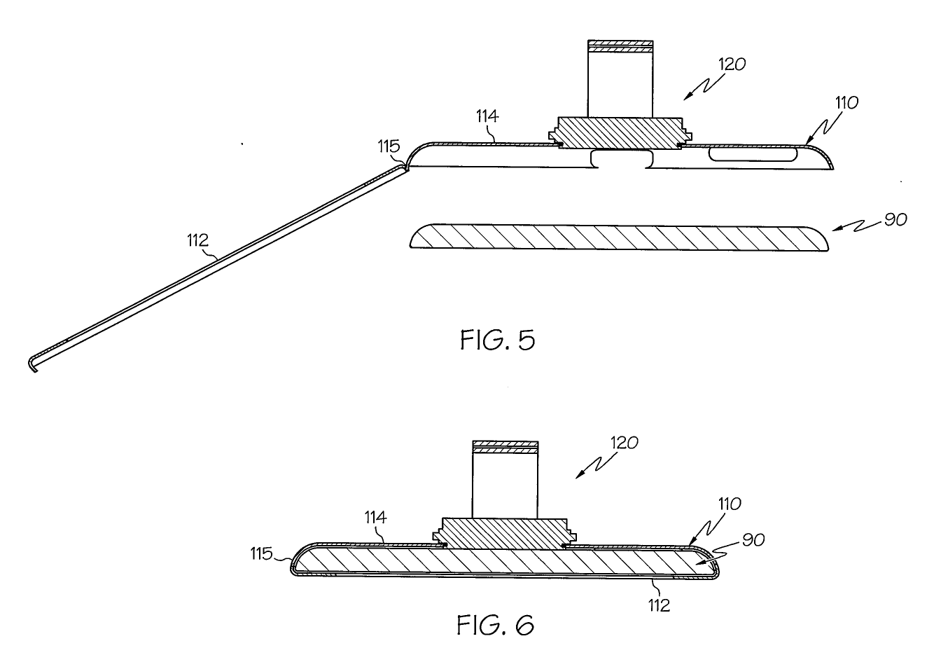

As depicted in FIG. 5, the shell 110 may be placed in an open position such that the first shell portion 112 does not enclose six faces of a generally cuboid electronic device 90. The electronic device 90 may be nestled within the second shell portion 114 and the first shell portion 112 is articulated about the hinge portion 115 such that the first shell portion 112 is aligned with the second shell portion 114. The first shell portion 112 may then be coupled to the second shell portion 114 to secure the electronic device 90 within the shell 110.

Shells 110 made according to this embodiment may be made from polymers that exhibit high relative strength and stiffness, for example, acrylonitrile butadiene styrene (ABS), polycarbonate, or combinations thereof. Shells 110 made with these materials may exhibit rigidity, which may protect the enclosed electronic device 90 from damage due to abrasion, impact, and/or compressive loading. To increase the tactile feel of shells 110 made from these materials, the external surfaces of the shell 110 may be coated with a polymeric compound that exhibits reduced hardness as compared with the shell material. Such coatings may provide a user with a “rubberized” feel to the shell 110 as to assist the user's grip on the shell 110 such as, for example, elastomers, silicone rubbers, rubber, or rubberized materials.

Another embodiment of the shell 310 is depicted in FIG. 7. In this embodiment, the first shell portion 312 and the second shell portion 314 are integrated with one another to form the shell 310. Similar to the embodiment discussed in regard to FIGS. 4-6, the display opening 313 passes through the bezel 311, which is positioned along the first shell portion 312. The electronic device 90 is inserted into the shell 310 by elastically deforming the bezel 311 around the electronic device 90. The electronic device 90 is, therefore, inserted between the first shell portion 312 and the second shell portion 314. Shells 310 made according to this embodiment may be made from polymers that exhibit high relative elasticity and tear strength, for example elastomers, silicone rubbers, rubber, or rubberized materials.

Cases according to the present disclosure allow a user to reposition an electronic device 90 while maintaining control without having to apply a substantial grasping force to the electronic device 90. This may be beneficial to users who wish to support the electronic device 90 for extended periods of time without having to grasp the case 100. Cases 100 according to the present disclosure may be ergonomically superior to cases where the user must grasp the case directly (e.g., a case without a handle), because cases 100 according to the present disclosure allow a user to support the electronic device 90 using larger muscle groups than the muscles (e.g., smaller muscle groups) used to grasp the case 100 alone. This may allow a user to hold and maneuver the electronic device 90 for longer periods of time as compared with cases where the user must grasp the case 100 directly.

Additionally, cases 100 according to the present disclosure may allow the user to quickly and reliably reposition the electronic device 90 through a variety of orientations, including a portrait orientation and a landscape orientation. Without repositioning his or her hand inside the internal envelope 122 of the handle 120, a user may rotate the shell 110 of the case 100 and thus the electronic device 90 contained therein about the axis of rotation 118. The ability to rotate the shell 110 and the enclosed electronic device 90 may be beneficial for electronic devices 90 that include accelerometers that adjust screen orientation based on position.

Examples of such electronic devices 90 include, but are not limited to, smartphones (for example, the APPLE iPhone 4®, the DROID INCREDIBLE by HTC®, and the RIM BLACKBERRY STORM 2®); portable music players (for example, the APPLE iPod Touch®, the MICROSOFT ZUNE HD®, and the SONY X-SERIES WALKMAN®); and tablet computers (for example, the APPLE iPad 2®, the MOTOROLA XOOM®, and the RIM BLACKBERRY PLAYBOOK®). As a user rotates one of these electronic devices 90, accelerometers within the electronic device 90 are used to determine the rotational orientation of the electronic device 90. The electronic devices 90 may change the orientation of the icons and/or images on the screen to display them in a vertical orientation for the user. Therefore, a user of such an electronic device 90 may choose to modify the orientation of the electronic device 90 to modify the screen orientation based on a particular input or output operation of the electronic device 90. For example, a user may prefer to orient the electronic device 90 in a landscape orientation when entering text via a virtual keyboard, while the user may prefer to orient the electronic device 90 in a portrait orientation when viewing an electronic document.

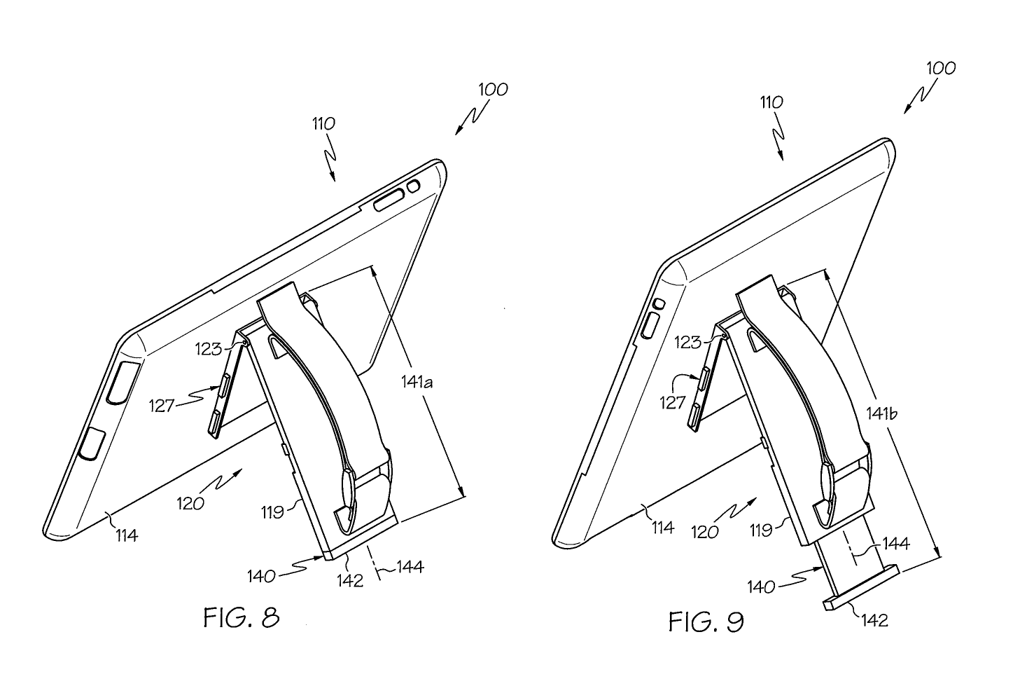

As discussed above, a user may selectively position the handle 120 in one of a closed position or a deployed position. By placing the handle 120 in the deployed position, a user may rest the case 100 against a surface such that the shell 110 and the handle 120 support the case 100 in a free-standing condition, i.e., without additional support, or interaction from the user. When the case 100 and the enclosed electronic device 90 is supported in a free-standing condition, the electronic device 90 is held in a generally upright, or partially reclined, orientation without further intervention from the user. Additionally, because the handle 120 rotates about the axis of rotation 118, the handle 120 can be rotated through a variety of positions, and can be positioned to support the case 100 in a landscape orientation or a portrait orientation, as depicted in FIGS. 8 and 9, respectively. The extendible strap assembly 130 need not be removed from the handle 120 for the handle 120 to function as both a stand and as a hand-hold grip.

As discussed above, the support end 140 may translate along a longitudinal axis 144 of the handle bracket 119 between a stored position and an extended position. Referring now to FIG. 8, when the handle 120 is in a deployed position and the case 100 is supported in a landscape orientation, the support end 140 may be positioned in a stored position relative to the handle 120 (i.e., not extended along longitudinal axis 144 of the handle 120). The support end 140 and the second shell portion 114 contact a surface to support the case 100 in a partially reclined orientation. In this orientation, the distance 141a from the shell 110 to the support end 140 may be minimized.

Referring now to FIG. 9, the handle 120 may be rotated relative to the shell 110 such that the support end 140 and the second shell portion 114 support the case 100 in a portrait orientation. Because the electronic device 90 itself is rectangular, to maintain the degree of incline as when being supported in the landscape position depicted in FIG. 8, the support end 140 may be extended along longitudinal axis 144 of the handle bracket 119 such that the support end 140 is an increased distance 141b away from the shell 110 when measured along the handle 120.

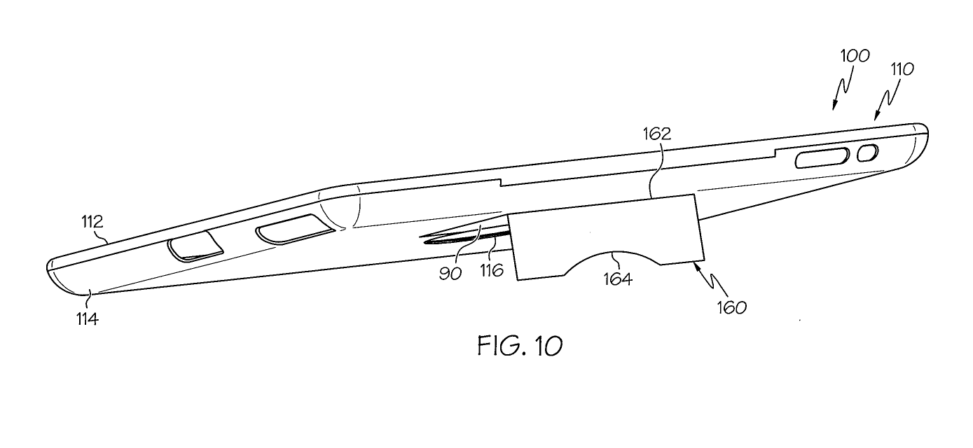

Referring now to FIG. 10, embodiments of the case 100 may include an extendible prop 160. The extendible prop 160 may be stowed along the second shell portion 114 when not in use, such that the extendible prop 160 is embedded in the second shell portion 114. The extendible prop 160 may rotate about a hinge portion 162 between the stowed position and the deployed position. The hinge portion 162 may be integrated into both of the second shell portion 114 and the extendible prop 160. Alternately, the hinge portion 162 may be a discrete element from the second shell portion 114 and the extendible prop 160. One or more of the extendible prop 160 or the second shell portion 114 may include a finger relief 164. The finger relief 164 includes a spacing between the extendible prop 160 and the second shell portion 114 that allows a user to insert his or her finger between the extendible prop 160 and the second shell portion 114 to grip the extendible prop 160 and rotate it from a stowed position towards a deployed position.

The extendible prop 160 extends from the second shell portion 114 and is positioned to support the case 100, along with the enclosed electronic device 90 in a supine orientation, where the display opening 113 (not shown) faces generally upwards. Supporting the electronic device 90 in such an orientation may provide a position that allows a user to type on the touchscreen of the electronic device 90 in comfort.

It should now be understood that cases for electronic devices may include a handle that rotates relative to a shell, such that a user can reposition the orientation of the electronic device without having to change his or her grip on the handle. Further, the handle and the shell can support the case in a reclined orientation, such that a user does not have to support the electronic device.

It is further noted that terms like “preferably,” “generally,” “commonly,” and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention.

For the purposes of describing and defining the present invention it is additionally noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention.

What is claimed is:

1. A case for an electronic device, comprising:
a shell comprising a display opening, the shell adapted to at least partially surround the electronic device; and
a handle coupled to the shell,
wherein the handle is adapted to rotate relative to the shell about an axis of rotation.

2. The case of claim 1, wherein an internal envelope of the handle is adjustable.

3. The case of claim 1, wherein the handle comprises an extendable strap assembly.

4. The case of claim 3, wherein the extendable strap assembly comprises a tongue attached to a first portion of a handle bracket and a cinch ring coupled to a second portion of the handle bracket, wherein a portion of the tongue passes through the cinch ring and is selectively affixed onto itself.

5. The case of claim 4, wherein a first tongue section comprises one of a hook material or a loop material, and a second tongue section comprises one of a loop material or a hook material adapted for engaging the hook material or the loop material, respectively, of the first tongue section.

6. The case of claim 1, wherein the shell further comprises a first shell portion and a second shell portion, and the display opening passes through a bezel disposed along the first shell portion.

7. The case of claim 6, wherein the shell further comprises a circular opening along the second shell portion, and the handle comprises a retention element, wherein the retention element engages the circular opening to selectively couple the handle to the shell, and the circular opening defines the axis of rotation.

8. The case of claim 7, wherein the retention element comprises at least one depressible key.

9. The case of claim 6, wherein the shell further comprises a hinge portion, and the first shell portion articulates relative to the second shell portion between an open position and a closed position.

10. The case of claim 6, wherein the second shell portion further comprises an extendible prop, wherein the extendible prop is adapted to support the case in a free-standing condition in a supine orientation.

11. The case of claim 1, wherein the handle is adapted to support the case in a free-standing condition in a landscape orientation and a portrait orientation.

12. The case of claim 1, wherein the handle comprises support end located at a position remote from the shell.

13. The case of claim 12, wherein a length of the handle from the support end to the shell along a longitudinal axis of the handle is adjustable.

14. A case for an electronic device, comprising:
a shell configured to at least partially surround the electronic device, the shell comprising a first shell portion and a second shell portion, wherein the first shell portion comprises a display opening passing through a bezel; and
a handle coupled to the second shell portion,
wherein the handle is adapted to rotate relative to the shell about an axis of rotation.

15. The case of claim 14, wherein the handle comprises a handle bracket that is adapted to rotate about a handle hinge between a stored position and a deployed position.

16. The case of claim 14, wherein the handle comprises an extendable strap assembly comprising a tongue attached to a first handle bracket portion and a cinch ring attached to a second handle bracket portion, wherein a portion of the tongue passes through the cinch ring and is selectively affixed onto itself.

17. A case for an electronic device, comprising:
a shell comprising a first shell portion, a hinge portion, and a second shell portion, the first shell portion comprising a bezel and a display opening that passes through the bezel, the second shell portion comprising a plurality of control feature openings, wherein the first shell portion and the second shell portion at least partially surround the electronic device;
a handle coupled to the second shell portion,
wherein the handle is rotatable relative to the shell about an axis of rotation.

18. The case of claim 17, wherein the handle comprises:
a handle bracket further comprising:
a first handle bracket portion and
a second handle bracket portion; and
a strap assembly further comprising:
a tongue attached to the first handle bracket portion and
a cinch ring coupled to the second handle bracket portion, wherein the tongue passes through the cinch ring and is selectively affixed onto itself.

19. The case of claim 17, wherein the handle comprises a support end located at a position remote from the shell, and the support end and at least part of the second shell portion are adapted to support the case in a free-standing condition in a landscape orientation and a portrait orientation.

20. The case of claim 19, wherein a length of the handle from the support end to the shell along a longitudinal axis of the handle is adjustable.
